(19) United States
(12) Patent Application Publication
(10) Pub. No.: US 2020/0177278 A1
(43) Pub. Date: Jun. 4, 2020

(54) Receiver Assembly, Data Communications System, and Data Communications Method

(71) Applicants: Dominic Christopher O'Brien, Oxford (GB); Stephen Collins, Oxford (GB); Ifor David William Samuel, St. Andrews (GB); Pavios Manousiadis, St. Andrews (GB); Graham Alexandria Tumbill, St Andrews (GB); Harald Haas, Edinburgh (GB)

(72) Inventors: Dominic Christopher O'Brien, Oxford (GB); Stephen Collins, Oxford (GB); Ifor David William Samuel, St. Andrews (GB); Pavios Manousiadis, St. Andrews (GB); Graham Alexandria Tumbill, St Andrews (GB); Harald Haas, Edinburgh (GB)

(21) Appl. No.: 16/319,650

(22) PCT Filed: Jul. 17, 2017
(86) PCT No.: PCT/GB2017/052096

§ 371 Date: Jan. 22, 2019

(30) Foreign Application Priority Data
Jul. 22, 2016 (GB) 1612740.9

(51) Int. Cl. H04B 10/116; H04B 10/67; H01L 31/055; H01L 33/50; G02B 5/18

(52) U.S. Cl. CPC H04B 10/116; H04B 10/677; G02B 5/1876; H01L 33/502; H01L 31/055

(57) ABSTRACT

A receiver assembly (100) and data communications method are disclosed. In one arrangement, a receiver assembly (100) comprises a concentration stage (14). The concentration stage (14) receives radiation via an input surface (120) and outputs concentrated radiation via an output surface (122). The concentration stage comprises a wavelength converting member (6) that converts radiation to longer wavelength radiation. An optical element (102) is provided which is such that if a plane wave of radiation is incident on the optical element a spatial distribution of radiation derived from the plane wave on the input surface of the concentration stage varies as a function of a direction of incidence of the plane wave relative to the optical element. A plurality of detectors (42) are provided, each detecting radiation output from a different portion of the output surface of the concentration stage.

The invention relates to optical data communications using optical concentrators.

Market research published in 2014 predicted that by 2019 there will be 11.5 billion mobile-connected devices in the world and that these devices will contribute to a tenfold increase in global mobile data traffic between 2014 and 2019. It is anticipated that high concentrations of devices using the RF spectrum will generate so much interference that service quality will be significantly degraded. A key part of the solution to this expected spectrum crunch is to exploit new parts of the electromagnetic spectrum to support mobile wireless communications.

A part of the electromagnetic spectrum not currently used widely for wireless communications is visible light. The possibility of exploiting this part of the spectrum economically is increasing, due to the growing use of light emitting diodes (LEDs) for lighting. Unlike some other lighting technologies, LEDs can be modulated at relatively high frequencies. For example, micro-LEDs can be modulated at frequencies up to 185 MHz. These frequencies are suitable for wireless communications using existing infrastructure. Other potential advantages of visible light communication (VLC) include the lack of electromagnetic interference, the ability to localise light within a space to support many users and the improved cyber-security arising from the fact that light does not penetrate walls.

For indoor VLC lighting LEDs can be used as transmitters with a high signal to noise ratio. Receivers will each need to incorporate a photodetector which converts the modulated light into a modulated electrical signal. To have a large enough bandwidth the photodetectors will typically have to be fairly small (possibly of the order of 100-300 μm diameter). The signal falling on such small photodetectors may be increased using an optical concentrator such as a lens or a compound parabolic concentrator. However, the area of typical concentrators is limited by the conservation of étendue (constant radiance theorem), which means that the maximum gain, Gₘₐₓ, for a concentrator with a field of view B is given by

$${G}_{max} = \frac{{n}^{2}}{{sin}^{2} θ} ,$$

where n is the refractive index of the concentrator.

The relationship between the étendue limited maximum theoretical optical gain and the half angle of the field of view of a concentrator is well-known. However, with gains of 1,000 or more the concentrator's aperture will have a diameter of less than 1 cm. Such small apertures will be vulnerable to being accidentally blocked. Furthermore, the high gain reduces the field of view (FOV). A gain of around 1,000 will be associated with a FOV of about 3°. This is likely to cause problems in many practical applications. For example, if VLC were to be used with handheld mobile terminals such as mobile phones or tablets, these would need to have concentrators with relatively large fields of view, for example around 20° or higher. Such fields of view would reduce the maximum theoretical gain of the concentrator to below 20. Unfortunately, a concentrator with a field of view of 20° or more will also have an aperture of 1 mm or less, and will therefore be vulnerable to blocking.

Changing the wavelength of radiation during the concentration process, using fluorescence for example, allows gains and/or fields of view to be achieved which are not constrained by conservation of étendue, and which can therefore be more favourable. Examples of arrangements based on this principle are disclosed for example in GB 2506383A and in ‘High gain, wide field of view concentrator for optical communications’, Steve Collins, Dominic C. O'Brien and Andrew Watt, OPTICS LETTERS, Vol. 39, No. 7, pp 1756-1759 Apr. 1, 2014.

Optical concentration refers to the process of receiving light using a relatively large collecting aperture and concentrating that light onto a much smaller area, such that the photon flux density on the smaller area is larger than the photon flux density on the larger area. There are many applications for concentrators, including in free space optical communications and power generation. In the case of optical communications, light carries an information signal, and an optical receiver uses a concentrator to collect light from the largest area possible and concentrate it on a photo-detector.

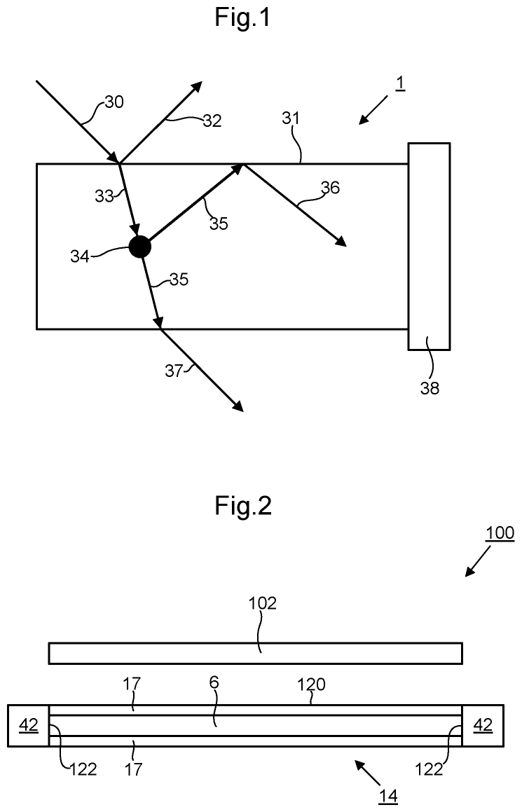

The principle of operation of a concentrator 1 comprising a wavelength converting element based on fluorescence is illustrated schematically in FIG. 1. Light 30 from a transmitter is incident on the front surface 31 of the concentrator 1, which acts as a collecting area of the concentrator 1. Some of this incident light will be reflected from the surface 31 (arrow 32) but most of the light will be transmitted into the concentrator 1 (arrow 33). Some of transmitted incident light will be absorbed by fluorophores 34 within the concentrator 1. Any fluorophore that has been excited by a photon of incident light might emit a photon with a longer wavelength in a random direction (arrows 35). Some of this emitted light will escape from the concentrator 1 (arrow 37) but most of it will be retained within the concentrator 1 by total internal reflection (arrow 36). If re-absorption by the fluorophore at the new wavelength is negligible this light will reach a detector 38 at an edge of the concentrator 1. Even if the retained light is absorbed by the fluorophore before it reaches the detector 38 it can still be emitted at an even longer wavelength, be retained by total internal reflection and reach the detector 38.

Increasing concentrator gain facilitates high speed data communications by enabling efficient use to be made of small, fast detectors.

It is an object of the invention to provide further improved apparatus and methods for data communications.

According to an aspect of the invention, there is provided a receiver assembly, comprising: a concentration stage configured to receive radiation via an input surface and output concentrated radiation via an output surface, wherein the concentration stage comprises a wavelength converting member configured to convert radiation to longer wavelength radiation; an optical element configured such that if a plane wave of radiation is incident on the optical element a spatial distribution of radiation derived from the plane wave on the input surface of the concentration stage varies as a function of a direction of incidence of the plane wave relative to the optical element; and a plurality of detectors, each detector being configured to detect radiation output from a different portion of the output surface of the concentration stage.

The wavelength conversion to longer wavelengths makes it possible to provide a wider field of view for a given level of gain or, conversely, a higher gain for a given field of view, then concentrators which do not use a wavelength converting member. Increasing the degree of concentration makes it possible for the detectors to be made smaller and therefore more efficient, for example faster and/or cheaper. The optical element and the plurality of detectors make it possible to distinguish between radiation incident on the concentration stage from different directions. This ability makes it possible to implement data communications in a multiple input, multiple output (MIMO) mode, thereby increasing the maximum rate of data transfer.

In an embodiment, the wavelength converting member comprises a plurality of wavelength converting elements and a concentration of the wavelength converting elements per unit area when viewed in a direction perpendicular to the input surface varies as a function of position over the input surface. This feature makes it easier to distinguish reliably between radiation incident on the concentration stage from different transmitters (and therefore from different directions) and/or allows transmitter systems to comprise larger numbers of individual transmitters and/or to locate transmitters closer together (thereby improving compactness at the transmitter system). The variation in concentration can be used to vary a sensitivity of the receiver assembly to differences of direction of incidence as function of direction of incidence, such that the receiver assembly can distinguish more sensitively for example between different radiation beams within selected solid angles in comparison with other solid angles.

In an embodiment, the wavelength converting elements are distributed in a medium and a thickness of the medium in a direction perpendicular to a nearest portion of the input surface varies as a function of position over the input surface. Alternatively or additionally, the number of the wavelength converting elements per unit volume varies as a function of position, at least in a direction parallel to the input surface. These approaches, individually or in combination, make it possible flexibly to enhance how radiation from different transmitters can be distinguished, at low manufacturing cost.

In an embodiment, the concentration stage comprises a plurality of radiation guides; each radiation guide has an elongate form with a length that is at least five times longer than all dimensions of the radiation guide perpendicular to the longitudinal axis; each radiation guide comprises a portion of the wavelength converting member and is thereby configured to convert radiation to longer wavelength radiation within the radiation guide; the input surface of the concentration stage comprises at least a portion of an outer lateral surface of each of the radiation guides; and each of the radiation guides is configured to guide the converted radiation to a longitudinal end surface of the radiation guide, the output surface of the concentration stage comprising at least a portion of the longitudinal end surface of each of the radiation guides.

Use of a plurality of elongate radiation guides enables radiation to be concentrated onto a point-like surface, thereby facilitating use of small detectors, which can operate efficiently at high speed and increase bandwidth of communication devices using the assembly. Furthermore, the inventors have recognised that radiation guides having the required geometry are widely available (e.g. optical fibres) and can be cost effectively adapted to achieve the functions of the invention. Radiation is also only output from the radiation guides via the longitudinal ends surfaces, meaning that detectors are only needed in these locations. This provides a convenient geometry for positioning the detectors and supporting electronics for the detectors.

In an embodiment, wavelength converting elements are distributed non-uniformly through a cross-section of the radiation guide. Varying the concentration of the wavelength converting elements provides flexibility to achieve an optimal balance between efficiently converting radiation to longer wavelength radiation (favoured by regions of relatively high wavelength converting element density) and providing a low absorption path for the converted radiation to travel to the detector (favoured by having paths of relatively low wavelength converting element density). The wavelength converting elements may be concentrated for example in regions where it is expected that incident radiation will be focussed by the particular geometry of the radiation guide.

In an embodiment, more than 95% of the wavelength converting elements may desirably be located within an azimuthal angle of 330 degrees relative to the longitudinal axis, averaged over the length of the radiation guide. Such an embodiment provides an angular region (the remaining 30 degrees) in which fewer wavelength converting elements are present, which may facilitate efficient entry of radiation into the radiation guide and subsequent distribution to the wavelength converting elements in other regions.

In an embodiment, a spatial density of wavelength converting elements in the radiation guide, averaged over the length of the radiation guide, varies as a function of radius relative to the longitudinal axis. This arrangement may be particularly easy to manufacture. In an embodiment, the radiation guide comprises a core of an optical fibre. High quality optical fibres are widely available and can be adapted in a cost-effective manner. For example, in an embodiment the radiation guide further comprises an outer layer on the core of the optical fibre and wherein the conversion of the received radiation to longer wavelength radiation is performed at least partially in the outer layer. The outer layer can be provided simply by replacing the outer cladding of a conventional optical fibre with the outer layer.

According to an aspect, there is provided a data communications method, comprising the following steps: using a concentration stage to receive radiation via an input surface and output concentrated radiation via an output surface; using a wavelength converting member in the concentration stage to convert radiation to longer wavelength radiation; providing an optical element configured such that if a plane wave of radiation is incident on the optical element a spatial distribution of radiation derived from the plane wave on the input surface of the concentration stage varies as a function of a direction of incidence of the plane wave relative to the optical element; and detecting radiation output from the output surface using a plurality of detectors, each detector being configured to detect radiation output from a different portion of the output surface.

Embodiments of the invention will now be described, by way of example only, with reference to the accompanying drawings in which corresponding reference symbols represent corresponding parts, and in which:

FIG. 1 is a schematic side sectional view of a concentrator illustrating the principle of operation of a concentrator comprising wavelength converting elements;

FIG. 2 is a schematic side sectional view of a receiver assembly;

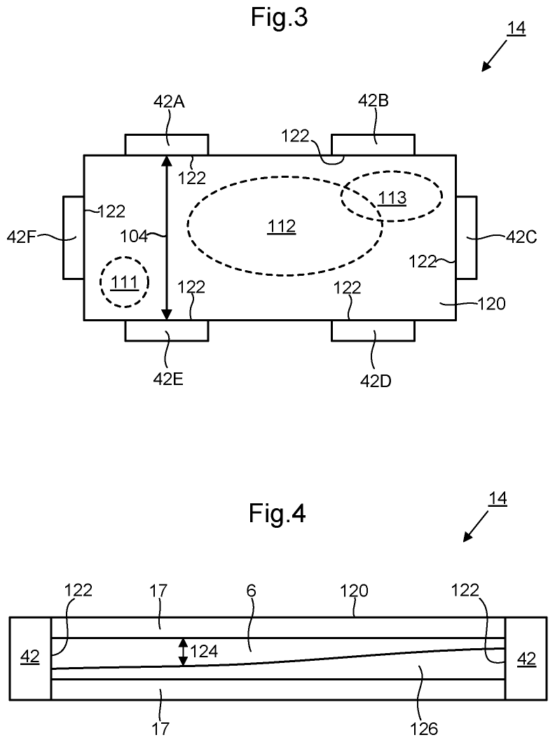

FIG. 3 is a schematic top view of a concentration stage of a receiver assembly showing example distributions of energy from different transmitters;

FIG. 4 is a schematic side sectional view of a concentration stage with a wavelength converting medium of non-uniform thickness;

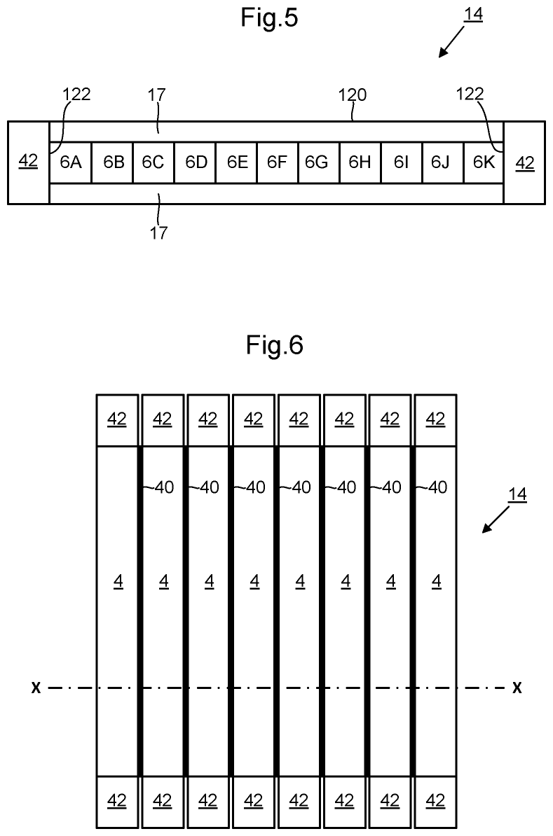

FIG. 5 is a schematic side sectional view of a concentration stage having a wavelength converting member formed from a plurality of regions;

FIG. 6 is a schematic top view of a concentration stage comprising a plurality of elongate radiation guides;

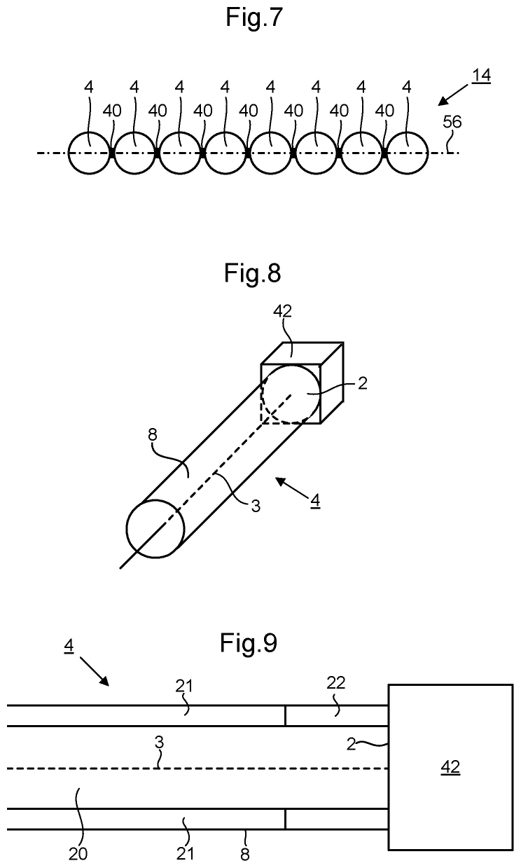

FIG. 7 is a schematic side sectional view of the concentration stage of FIG. 6 relative to line X-X;

FIG. 8 is a schematic perspective view of one of the radiation guides in a concentration stage of the type depicted in FIGS. 6 and 7;

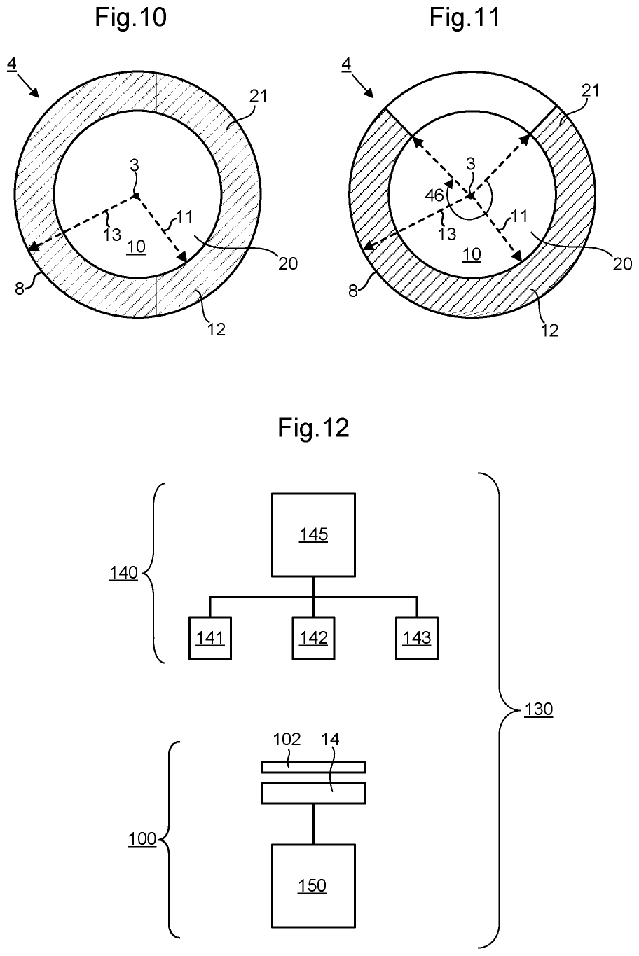

FIG. 9 is a schematic side sectional view of the radiation guide of FIG. 8;

FIG. 10 is a schematic end sectional view of a radiation guide of the type depicted in FIG. 8 in which wavelength converting elements are provided only in a radially outer region;

FIG. 11 is a schematic end sectional view of a radiation guide of the type depicted in FIG. 8 in which wavelength converting elements are provided only in a radially outer region and within a range of azimuthal angles of less than 330 degrees;

FIG. 12 depicts a data communications system comprising a receiver assembly according to an embodiment;

FIG. 13 is a photograph depicting a MIMO communications experiment during operation;

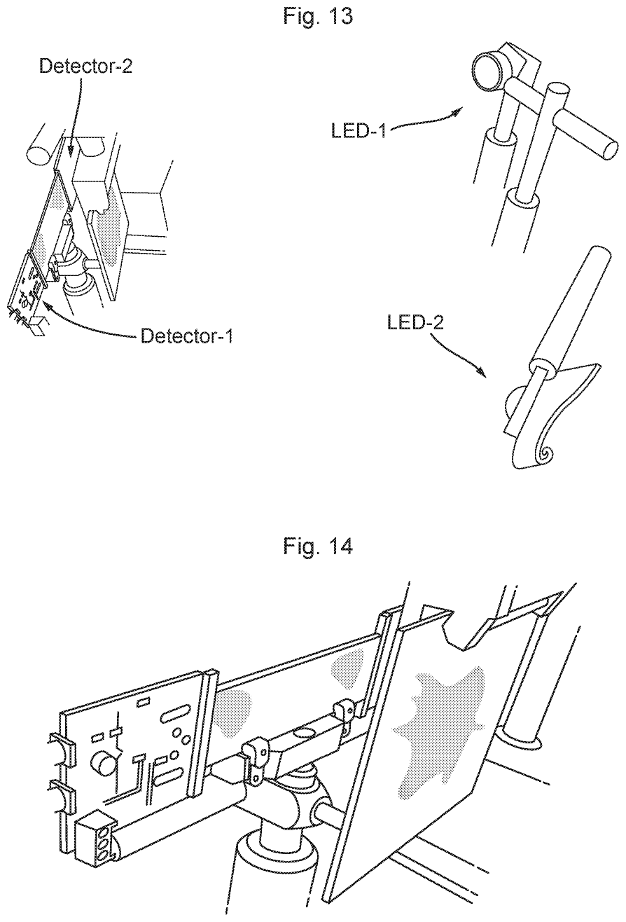

FIG. 14 is a photograph showing a magnified view of light impinging on the Fresnel lens and concentration stage shown in FIG. 13; and

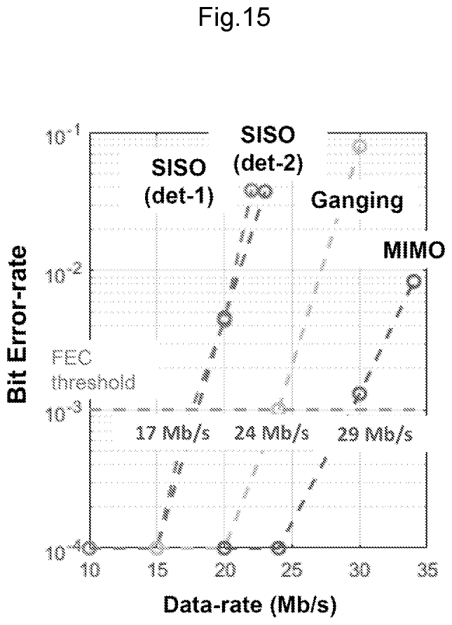

FIG. 15 is a graph showing the results of the experiment depicted in FIGS. 13 and 14.

Optical concentration can be used to reduce the size of photo-detectors required in free space optical communications applications, particularly where a wavelength converting material is used to convert radiation to longer wavelength radiation within a concentration stage. Smaller photo-detectors have higher bandwidths on average. The inventors have recognised that further increases in channel capacity can be achieved by providing a receiver assembly that uses wavelength conversion and is also adapted to operate in a multiple input, multiple output (MIMO) mode. Examples of how this may be achieved are described below with reference to the figures.

In an embodiment, an example of which is depicted in FIG. 2, there is provided a receiver assembly 100. The receiver assembly 100 is configured for use in data communications. The receiver assembly 100 receives electromagnetic radiation (from above in the example of FIG. 2) modulated with communication information which can be extracted at a later stage. The receiver assembly 100 comprises a concentration stage 14. The concentration stage 14 receives radiation via an input surface 120 (from above in the example of FIG. 2) and outputs concentrated radiation via an output surface 122. An average photon flux density on the output surface 122 (averaged over time and space) is higher in use than an average photon flux density on the input surface 120 (averaged over time and space). The concentration stage 14 may take various forms. In the particular example of FIG. 2 the concentration stage 14 comprises a rectangular, planar slab. The input surface 120 comprises at least a portion of at least one of the large planar faces of the slab (the upper planar face in the example of FIG. 2). The output surface 122 comprises at least a portion of at least one of the side surfaces (two of the side surfaces, opposite to each other, in the example of FIG. 2). In other embodiments the input surface 120, the output surface 122, or both, may be configured differently, for example being non planar or oriented differently relative to each other.

The concentration stage 14 comprises a wavelength converting member 6. The wavelength converting member 6 converts radiations to longer wavelength radiation. The wavelength converting member 6 absorbs radiation of a first wavelength or range of wavelengths and re-emits the radiation at a second wavelength or range of wavelengths that is different to the first. The conversion involves shifting power from shorter wavelengths towards longer wavelengths. In an embodiment, the wavelength converting member 6 has a short response time, for example of 1 microsecond or less, optionally 10 nanoseconds or less, optionally 1 nanosecond or less, in order to facilitate high bandwidth data communications.

In an embodiment the wavelength converting member 6 comprises a plurality of wavelength converting elements. The plurality of wavelength converting elements may comprise fluorophores, which operate on the basis of fluorescence. The wavelength converting elements may comprise fluorescent dye. Alternatively or additionally, the wavelength converting elements may comprise quantum dot wavelength converters, for example solution processed quantum dots. Solution processed quantum dots are particularly suitable for this application because they have tuneable absorption and emission characteristics, large luminescence quantum yields and Stokes shifts compatible with minimal re-absorption losses. The one or more wavelength converting elements may optionally be substantially transparent to converted radiation so as to reduce or minimize re-absorption losses.

In an embodiment, the conversion of the received radiation to longer wavelength radiation comprises one or more of the following: conversion of infrared or near-infrared radiation to infrared radiation or near-infrared radiation having a longer wavelength, conversion of UV radiation to visible radiation, conversion of UV radiation to infrared or near-infrared radiation, conversion of visible radiation to visible radiation having a longer wavelength, and conversion of visible radiation to infrared or near-infrared radiation. In one particular embodiment, radiation is absorbed at approximately 475 nm and re-emitted at approximately 600 nm, with a corresponding confinement structure 17 being provided that substantially passes radiation having a wavelength of approximately 475 nm and traps radiation having a wavelength of approximately 600 nm. Such a system may be implemented using the dye Ru(BPY)3 for example. Many other dyes may be used. Alternatively or additionally, quantum dots may be used. For example, Qdot® (Life Technologies Corporation) quantum dots may be used, which are available in various different formats with different absorption and emission characteristics. Qdot® 605, or Qdot® 655, which have respective emission maxima of about 605nm and about 655 nm may be used for example.

The shape of the wavelength converting member 6 is not particularly limited, making it possible to tailor the shape to suit the particular application in which the receiver assembly 100 is to be incorporated. The receiver assembly 100 can therefore be incorporated into a wide variety of devices with a minimum of visual impact relative to the same devices without the receiver assembly 100. In an embodiment, the wavelength converting member 6 has a thickness that is smaller than the length and/or width of the member 6. In an embodiment, the wavelength converting member 6 has a substantially sheet-like form, for example having a thickness that is at least 10 times, optionally at least 50 times, optionally at least 100 times, smaller than the length and/or width of the member 6. A large collection area (input surface 120) in a relatively small volume device can thus be provided. In an example embodiment, the wavelength converting member 6 is substantially planar.

In an embodiment, the concentration stage 14 comprises a confinement structure 17 that substantially allows passage of radiation having a wavelength suitable for conversion by the wavelength converting member 6 in the concentration stage 14 from the outside of the confinement structure 17 to the inside of the confinement structure 17. The confinement structure 17 further substantially blocks passage of radiation that has been converted by wavelength converting member 6 in the concentration stage 14 from the inside of the confinement structure 17 to the outside of the confinement structure 17. Converted radiation may thus be directed efficiently to the output surface 122 via internal reflections from the confinement structure 17. The confinement structure 17 thus reduces losses.

The confinement structure 17 may comprise two substantially planar elements (e.g. dichroic plates) and the wavelength converting member 6 is located in between the two substantially planar elements. Converted radiation is trapped by the two planar elements and guided towards the output surface 122.

Where the concentration stage 14 comprises a confinement structure 17, the confinement structure 17 may concentrate radiation towards the output surface 122 of the concentration stage 14.

The receiver assembly 100 further comprises a plurality of detectors 42. Each detector 42 detects radiation output from a different portion of the output surface 122 of the concentration stage 14. In the example of FIG. 2, one detector 42 detects radiation output from a lateral surface on the left side and another detector 42 detects radiation output from a lateral surface on the right side. Other detectors 42 may be provided. The inventors have recognised that the provision of plural detectors 42 provides the basis for implementing a MIMO communications system if radiation incident on the concentration stage 14 from a first transmitter results in a distribution of radiation on the input surface 120 which distinguishes that radiation from radiation incident on the concentration stage 14 from a second transmitter at a different location.

The inventors have found it is often difficult to distinguish between radiation transmitted from different transmitters when the radiation is incident directly on an input surface of a concentration stage. This is because the radiation from the transmitters tends to illuminate the input surface relatively uniformly, which results in a relatively uniform distribution of intensity over the input surface. The relatively uniform distribution of intensity will not vary sufficiently strongly as a function of a location of the transmitter for the detectors 12 to be able to distinguish between transmitters transmitting from different locations.

The inventors have recognised however that the situation can be improved radically by positioning an optical element 102 between the transmitters and the input surface 120, as shown in the example of FIG. 2. The optical element 102 acts to modify the intensity distribution on the input surface 120 so that it is less uniform and varies more strongly as a function of the location of the transmitter. In embodiments, including the example of FIG. 2, the optical element 102 is of a type which has the following effect. If a plane wave of radiation is incident on the optical element 102 a spatial distribution of radiation derived from the plane wave on the input surface 120 will vary as a function of a direction of incidence of the plane wave relative to the optical element 102. In use, radiation from a transmitter may not necessarily consist of a plane wave, but configuring the optical element 102 in this way ensures that the spatial distribution of intensity on the input surface 120 will be sufficiently non-uniform and dependent on the direction of incidence of the radiation to make it possible from analysis of an output from the plurality of detectors 42 to distinguish between radiation from different transmitters for a wide range of different waveforms received from the transmitters at the receiver assembly 100.

In an embodiment, the plurality of detectors 42 are arranged such that if a plane wave of radiation is incident on the optical element 102 each detector 42 receives a respective proportion of an energy from the plane wave and the detectors 42 are arranged such that the respective proportions depend on the spatial distribution of radiation on the input surface 120 and therefore on the direction of incidence of the plane wave.

FIG. 3 is top view of a concentration stage 14 of the general type shown in FIG. 2 (rectangular slab). FIG. 3 illustrates schematically how the optical element 102 can provide different distributions of energy over the input surface 120. In this particular example, the concentration stage 14 is depicted with six different detectors, labelled 42A-F. Broken lines schematically delimit three different regions 111-113 into which radiation from three different transmitters has been concentrated by the optical element 102 (not shown). In the absence of the optical element 102, the same radiation from the transmitters would have been distributed substantially uniformly over the whole of the input surface 120. The concentration of the radiation into the regions 111-113 results in a different distribution of energy between the plural detectors 42A-F than would have been the case without the optical element 102.

In an embodiment, the plural detectors 42A-F can distinguish between radiation concentrated onto different regions 111-113 due to absorbance at wavelengths emitted by the wavelength converting member 6 being sufficiently high that detectors nearer to the respective regions 111-113 receive a significantly larger proportion of the incident radiation than detectors located further away. In this embodiment and other embodiments of this type, an absorbance within the concentration stage 14 is arranged to satisfy the following criterion: if a beam of radiation after conversion within the wavelength converting member 6 (i.e. having the wavelength characteristics of radiation that is emitted by the wavelength converting member 6) were to propagate along the entire length of a shortest optical path between two different ones (i.e. at least two different ones) of the plurality of detectors 42A-F, the amplitude of the radiation would be reduced by at least 1%, optionally by at least 5%, optionally by at least 10%, optionally by at least 25% from the start of the optical path to the end of the optical path. An example of such a shortest optical path between two different ones of the plurality of detectors which satisfies the criterion is shown in FIG. 3 and labelled 104. In this particular example, the shortest path 104 is between detectors 42A and 42E. Other shortest optical paths between different pairs of detectors may or may not also satisfy the criterion. In an embodiment the reduction of amplitude is at least 50%, optionally at least 75%, optionally at least 90%.

In the example of FIG. 3, the proportion of energy input into region 113 that is received by detectors 42B and 42C would be significantly higher than the proportion received by any of the other detectors 42A and 42D-F, due to the absorption, because detectors 42B and 42C are significantly closer to the region 113 than the other detectors. The amount of absorption that occurs between the region 113 and the detectors is comparatively lower for the detectors 42B and 42C than for any of the other detectors 42A and 42D-F. For region 112, the relatively proportions are different, with approximately equal proportions of the energy being expected to reach detectors 42A, 42B, 42D and 42E (because they are roughly equidistant from the region 112) and slightly lower, but approximately equal proportions, expected also to reach the detectors 42C and 42F. For region 111, we would expect more energy to reach the detectors 42E and 42F. These differences in the relative proportions of energy received by the different detectors make it possible to distinguish between radiation received from each of the three transmitters even if that radiation reaches the receiver assembly simultaneously and even if the radiation is relatively uniform (e.g. plane wave) when it reaches the receiver assembly 100. The receiver 2 assembly 100 can therefore carry out communications using a MIMO mode and thereby increase the maximum data transfer rate of the data communications channel The receiver assembly 100 is effectively operating as a plurality of receivers.

The arrangement of FIG. 3 is an example of an embodiment in which the plurality of detectors 42 comprises at least two detectors which receive radiation output from portions of the output surface 122 that are non-parallel. In this example, the output surface 122 has portions on each of the four peripheral sides of the rectangular slab, two of which are perpendicular to the other two. Providing detectors on surfaces which are non-parallel allows the receiver assembly to distinguish between different spatial distributions of radiation in two dimensions (e.g. in x- and y-axes). For example, in the case where the optical element focusses incoming planar radiation to spots on the input surface, the receiver assembly can distinguish between spots having differences in position in either or both of the x- and y-axes (rather than, for example, only in a single direction parallel to all of the output surfaces in the alternative case where all of the output surfaces are parallel—see, for example, the embodiment discussed below with reference to FIGS. 6 and 7). This provides greater flexibility and helps to distinguish effectively between a wider variety of incoming radiation beams.

The above-described mechanism based on absorbance is not the only mechanism by which the relative proportions of energy arriving at the detectors 42 can be made to vary as a function of the spatial distribution of radiation on the input surface 120. Non-limiting examples of arrangements which can be combined with the absorbance mechanism discussed above (e.g. by using re-absorbance by the wavelength converting elements themselves at least partly as the basis for the absorbance mechanism), or which can be provided separately from that mechanism, are described below.

In an embodiment, the wavelength converting member 6 comprises a plurality of wavelength converting elements and a concentration of the wavelength converting elements per unit area when viewed in a direction perpendicular to the input surface 120 varies as a function of position over the input surface 120. The variation in concentration per unit area may be such that an average concentration of the wavelength converting elements per unit area, averaged over at least 5% of the input surface 120, varies by at least 1%, optionally by at least 5%, optionally by at least 10% as a function of position over the input surface 120.

In an embodiment, as depicted schematically in FIG. 4, the wavelength converting elements are distributed in a medium and a thickness 124 of the medium (the region labelled 6 in FIG. 4) in a direction perpendicular to a nearest portion of the input surface 120 varies as a function of position over the input surface 120. Region 126 comprises a filler material in which substantially no wavelength converting elements are present. The thickness 124 may vary by at least 1%, optionally by at least 5%, optionally by at least 10%, optionally by at least 25%, optionally by at least 50%, optionally by at least 75%, as a function of position over the input surface 120. FIG. 4 shows a thickness 124 varying from left to right but it will be understood that the thickness 124 could alternatively or additionally vary into and/or out of the plane of the page. The variation in thickness 124 changes the way in which the relative proportions of energy received by the plurality of detectors 42 is dependent on a spatial distribution of the energy over the surface of the input surface 120, thereby providing control over how signals from different transmitters can be distinguished from one another (for example by making the receiver assembly able to distinguish better between transmitters within certain selected solid angles than between transmitters within other solid angles).

Alternatively or additionally, the number of wavelength converting elements per unit volume within the medium containing the wavelength converting elements may be made to vary as a function of position, at least in a direction parallel to the input surface 120. The variation in number per unit volume may be such that an average number per unit volume, averaged over at least 5% of the medium, varies by at least 1%, optionally by at least 5%, optionally by at least 10%, optionally by at least 25%, optionally by at least 50%, optionally by at least 75%, as a function of position, at least in a direction parallel to the input surface 120. An example arrangement is shown in FIG. 5. The wavelength converting member 6 is divided into a plurality of regions 6A-K. Two or more of the regions 6A-K contain different numbers of wavelength converting elements per unit volume. The concentration of the wavelength converting elements per unit area when viewed in a direction perpendicular to the input surface 120 thus varies as a function of position and provides a similar effect to the variation in thickness of the medium containing the wavelength converting elements as described above with reference to FIG. 4.

FIGS. 6 and 7 depict an example of an alternative embodiment in which the concentration stage 14 is formed from a plurality of radiation guides 4. A single one of the radiation guides 4 is depicted in FIGS. 8 and 9. Each radiation guide 4 has an elongate form with a length that is at least five times longer than all dimensions of the radiation guide 4 perpendicular to the longitudinal axis 3, optionally at least 10 times longer, optionally at least 25 times longer, optionally at least 50 times longer. In the example shown the radiation guide 4 has a circular cross-section. The longest dimension perpendicular to the longitudinal axis 3 is therefore the diameter of the circular cross-section. The radiation guide 4 is therefore at least five times longer than the diameter of the cross-section of the radiation guide 4 in the case where the cross-section of the radiation guide 4 is circular.

Each radiation guide 4 comprises a portion of the wavelength converting member 6 and radiation is accordingly converted to longer wavelength radiation within each radiation guide 4. Cross-sectional views showing example distributions of wavelength converting elements are shown in FIGS. 10 and 11.

The input surface 120 of the concentration stage 14 in this embodiment comprises at least a portion of an outer lateral surface 8 of each of the radiation guides 4.

Each of the radiation guides 4 guides the converted radiation, for example by total internal reflection, to a longitudinal end surface 2 (shown in FIGS. 8 and 9) of the radiation guide 4. The geometry of the radiation guide 4 is such that radiation is concentrated from the outer lateral surface 8 to the longitudinal end surface 2. A photon flux density at the longitudinal end surface 2 (peak and/or spatially averaged) is therefore higher than a photon flux density at the outer lateral surface 8 (peak and/or spatially averaged). The output surface 122 of the concentration stage 14 comprises at least a portion of the longitudinal end surface 2 of each of the radiation guides 4. Pairs of detectors 42 each detect radiation output from respective longitudinal end surfaces 2 of a different one of the radiation guides 4.

In an embodiment, wavelength converting elements are distributed non-uniformly through a cross-section of each of one or more of the radiation guides 4. For example, a spatial density (number per unit volume), averaged over the length of each radiation guide 4, varies as a function of position in the cross-section.

In an embodiment, examples of which are illustrated in FIGS. 10 and 11, a spatial density of wavelength converting elements in each of one or more of the radiation guides 4, averaged over the length of the radiation guide 4, varies as a function of radius relative to the longitudinal axis 3. In an embodiment, the spatial density increases monotonically from the longitudinal axis 3 to the outer lateral surface 8 of each of one or more of the radiation guides 4.

In the examples of FIGS. 6-11, each radiation guide 4 comprises a core 20 of an optical fibre (e.g. an optical fibre with the outer cladding removed). Each radiation guide 4 further comprises an outer layer 21 on the core 20. In embodiments of this type (manufactured using the core 20 of an existing optical fibre) the conversion of the received radiation to longer wavelength radiation is performed at least partially in the outer layer 21. In the particular examples of FIGS. 6-11, the conversion occurs entirely within the outer layer 21. Wavelength converting elements are therefore provided exclusively in the outer layer 21, thereby providing the variation (a step change at the boundary between the core 20 and the outer layer 21 in this case) in the spatial density of wavelength converting elements with radius.

The outer layer 21 may be provided along the whole length of each of one or more of the radiation guides 4 or along only a portion of the whole length of each of one or more of the radiation guides 4. As shown in FIG. 9, in these examples the outer layer 21 is provided on a distal portion of the core 20 only (where the cladding has been removed). The cladding 22 is left in place on a proximal portion of the core 20 (nearest the detector 42). The cladding 22 may desirably provide a reflective interface with respect to the converted radiation in the region adjacent to the detector 42, thereby promoting efficient guiding of the converted radiation to the detector 42. As shown in FIG. 9, the region comprising the cladding 22 is short in these examples relative to the region where the wavelength converting outer layer 21 is provided, but in practice it could be made as long as is convenient to convey the radiation from where it is initially collected (via the outer lateral surface 8) to where it is decoded and processed further (via the detector 42).

In the example of FIG. 10 the wavelength converting elements 12 are distributed uniformly through the whole outer layer 21. This approach benefits from relative ease of manufacture. The wavelength converting elements 12 may alternatively be concentrated in regions where it is expected that incident radiation will be focussed by the particular geometry of the radiation guide 4. For example, in the case of a cylindrical radiation guide 4 and plane wave incident radiation, it would be expected that radiation would be focussed towards a rear side of the radiation guide 4 (the side opposite to the incident radiation) and wavelength converting elements 12 would desirably then be localised more towards the rear side than towards the front side.

In an embodiment, an example of which is shown in FIG. 11, more than 95%, optionally more than 98%, optionally more than 99%, optionally substantially all of, the wavelength converting elements 12 are located within an azimuthal angle 46 of 330 degrees, relative to the longitudinal axis 3. In the example of FIG. 11 the “front side” is the upper side in the orientation of the figure and the “rear side” is the lower side. The arrangement of FIG. 11 could be manufactured for example by replacing a selected angular portion of the outer cladding of an optical fibre with a medium comprising wavelength converting elements.

In the particular example of FIG. 11, substantially all of the wavelength converting elements 12 are located within the outer layer 21 and within an azimuthal angle 46 of 330 degrees.

In an embodiment each of one or more of the radiation guides 4 comprises an elongate region which comprises substantially no wavelength converting elements. In the case where the radiation guide 4 is formed from the core 20 of an optical fibre, the elongate region may conveniently be provided by the core 20 itself (or a portion of the core). This is the case in the examples of FIGS. 6-11. The elongate region extends from the detector 42 at least partially along the full length of the radiation guide 4. The elongate region helps to provide an efficient low absorption path to the detector 42 for radiation that has been converted by the wavelength converting elements, thereby improving efficiency. Using the core 20 of an optical fibre for the elongate region enables this improved efficiency to be obtained at low cost.

In an embodiment, as depicted in FIGS. 10 and 11, each of one or more of the radiation guides 4 comprises a first region 10 encompassing all material within a first radius 11 relative to the longitudinal axis 3 and a second region 12 encompassing all material from the first radius 11 to a second radius 13 relative to the longitudinal axis 3. In the examples of FIGS. 10 and 11, the first radius 11 corresponds to the outer radius of the core 20. The volume of the core 20 is therefore an example of the first region 10. The second radius 13 in this example corresponds to the outer radius of the outer layer 21. The volume of the outer layer 21 is therefore an example of the second region 12. The first and second regions 10, 12 are characterized by substantially all of the wavelength converting elements within the radiation guide 4 being located in the second region 12. Thus the second region 12 performs substantially all of the conversion to longer wavelength radiation, while the first region 10 efficiently guides the converted radiation to the receiver 5. The first radius 11 may optionally be at least 25%, optionally at least 50%, or optionally at least 75%, of the second radius 13. The second radius 13 may optionally be equal to the radius of a circular cross-section of the radiation guide 4. In an embodiment, a refractive index of the first region 10 is within 10% of the refractive index of the second region 12. The refractive index of the first region 10 may optionally be substantially equal to the refractive index of the second region 12. Reflection at the interface between the first and second regions 10,12 is therefore low, allowing converted radiation to pass efficiently from the second region 12 to the first region 10.

In an embodiment, each of one or more of the radiation guides 4 has a circular cross section along its whole length. The cross section may alternatively be elliptical, square, rectangular or any other regular or irregular shape which is capable of effectively guiding radiation. Each radiation guide 4 may be straight or curved along its longitudinal axis.

The optical element 102 may be configured to provide the desired functionality (i.e. such that if a plane wave of radiation is incident on the optical element 102 a spatial distribution of radiation derived from the plane wave on the input surface 120 of the concentration stage 14 varies as a function of a direction of incidence of the plane wave relative to the optical element 102) in a variety of different ways. In one embodiment, the optical element 102 comprises a lens. The lens may be configured to focus incident light for example. The lens may take various forms. In an embodiment, the lens comprises a Fresnel lens. In an embodiment the lens comprises a diffractive lens. Configurations in which the optical element 102 is substantially planar, which may be facilitated for example using a diffractive lens or a Fresnel lens, are desirable because this enables the optical element 102 to be provided in a particular compact form. The overall compactness of the receiver assembly 100 can therefore be increased. This is particularly desirable where it is desired to provide a substantially flat or planar receiver assembly 100, for example.

FIG. 12 depicts an example data communications system 130 comprising a receiver assembly 100 according to an embodiment. In this embodiment (and potentially in other embodiments) the receiver assembly 100 further comprises a decoder 150. The decoder 150 obtains information from radiation detected by the plurality of detectors 42. The information may have been modulated onto the radiation.

The data communications system 130 comprises a transmitter assembly 140 comprising a plurality of transmitters 141-143 and an encoder 145. In this embodiment a single encoder 145 is depicted but it will be understood that the encoder 145 could be implemented as plural separate encoder units, for example one encoder unit per transmitter. The encoder 145 applies a modulation to radiation transmitted by the transmitters 141-143 in order to transmit information. Each of the plurality of transmitters 141-143 is configured to transmit beams of radiation onto the optical element 102 of the receiver assembly 100 in a direction which is different to the direction of any of the other transmitters. As described above, these differences in direction of incidence of the radiation onto the optical element 102 will result in characteristic spatial distributions of the radiation on the input surface 120 which will enable the receiver assembly 100 to distinguish between radiation transmitted by different transmitters 141-143 even when the radiation is received at the same time. The data communications system 30 can therefore operate in a MIMO mode and thereby achieve increased bandwidth communications.

Thus, the transmitter assembly 140 may comprise at least a first transmitter 141 and a second transmitter 142 (in the particular example shown the transmitter system 140 comprises first, second and third transmitters 141-143). The first transmitter 141 and the second transmitter 142 (and any further transmitters 143) are configured to transmit beams of radiation onto the optical element 102 of the receiver assembly 100 from different directions. The transmitter assembly 140 transmits first information (an example of a unit of information) in radiation from the first transmitter 141 and second information (and further example of a unit of information) in radiation from the second transmitter 142 (and a further unit of information in radiation from each of any further transmitters 143 that are provided). The decoder 150 of the receiver assembly 100 is able to distinguish, due to the properties of the receiver assembly 100 discussed above, between first information and second information, due to the fact that the first information originates from radiation incident on the optical element 102 from a first direction (from the first transmitter 141) and the second information originates from radiation incident on the optical element 102 from a second direction (from the second transmitter 142), different from the first direction. In the particular example shown the decoder 150 is further able to distinguish third information (from the third transmitter 143) from radiation incident from a third direction.

In accordance with the above, a data communications method is made possible which comprises the following steps. A concentration stage is used to receive radiation via an input surface and output concentrated radiation via an output surface. A wavelength converting member in the concentration stage converts radiation to longer wavelength radiation. An optical element is provided which is such that if a plane wave of radiation is incident on the optical element a spatial distribution of radiation derived from the plane wave on the input surface of the concentration stage varies as a function of a direction of incidence of the plane wave relative to the optical element. Radiation output from the output surface is detected using a plurality of detectors. Each detector detects radiation output from a different portion of the output surface.

The optical element is used to increase a variance in amplitude of radiation incident on the input surface relative to the case if the optical element were not present. The optical element is defined by reference to a plane wave but it is understood that in use the radiation from different transmitters may not necessarily take the form of a plane wave at the optical element. Nevertheless, configuring the optical element as described will increase the efficiency with which radiation from different transmitters can be distinguished using the plurality of detectors.

The method further comprises using a transmitter assembly to transmit plural different radiation beams, each radiation beam having a different unit of information modulated thereon, and being incident onto the optical element from a different direction. The method further comprises decoding the detected radiation in such a way as to distinguish between the plural different units of information.

In further embodiments, one or more further concentration stages may be provided. In such embodiments, one or more further wavelength converting members may also be provided, each incorporated into one or more of the further concentration stages. Having a plurality of wavelength converting materials may be useful for example where it is desired for the transmitter to send signals in a plurality of different wavelength bands. In such a scenario each of the wavelength converting members could be configured to absorb radiation in a different one of the transmitted wavelength bands. Wavelength converting members that have fluorophores with absorption peaks may be particularly well suited to such embodiments.

FIGS. 13 and 14 depict a MIMO communications experiment performed by the inventors using embodiments of the disclosure. In FIG. 13, two white LEDs transmit independent data streams to a receiver assembly (on the left of the picture). Light is incident on a Fresnel lens (an example of the optical element referred to above) which separates the beams into two spots which are incident on a concentration stage comprising a planar confinement structure. This is shown in detail in the magnified view of FIG. 14.

Light incident on the concentration stage (largely the blue component of the white LEDs) is converted to green light which propagates in the plane of the confinement structure to the detectors at either end. Each detector receives a combination of modulated light ‘carrying’ the signal from both LED-1 and LED-2. The detector converts this light into an electrical signal, and subsequent signal processing allows the data streams from LED-1 and LED-2 to be recovered.

FIG. 15 shows the results of the experiment. The LEDs transmit on-off-keyed digital data at different bit rates. The received data is compared with that transmitted to obtain the Bit Error Ratio (BER) (the proportion of errored bits). The maximum data rate is achieved when the BER exceeds levels where standard error correction (known as FEC) cannot remove these errors. The BER vs. data rate is plotted in the figure, with the maximum rates annotated. These show that the individual channels (labelled SISO-DET1, SISO-DET2) achieve approximately 17 Mbits/s. A ‘perfect’ MIMO system would achieve 34 Mbits/s, as ideally the data rate grows linearly, whereas 29 Mbits/s is achieved in practice. This reduction is due to the crosstalk innate in the MIMO system. As a comparison, the case where LEDs both transmit the same data (Ganging) is also shown. Here the increased power received compared with the SISO case allows an increase from 17 to 24 Mbit/s. This shows that the MIMO, despite the crosstalk, offers the highest data rate.

1. A receiver assembly, comprising:
a concentration stage configured to receive radiation via an input surface and output concentrated radiation via an output surface, wherein the concentration stage comprises a wavelength converting member configured to convert radiation to longer wavelength radiation;
an optical element configured such that if a plane wave of radiation is incident on the optical element a spatial distribution of radiation derived from the plane wave on the input surface of the concentration stage varies as a function of a direction of incidence of the plane wave relative to the optical element; and
a plurality of detectors, each detector being configured to detect radiation output from a different portion of the output surface of the concentration stage.

2. The assembly of claim 1, wherein the plurality of detectors are arranged such that if a plane wave of radiation is incident on the optical element each detector receives a respective proportion of an energy from the plane wave and the detectors are arranged such that the respective proportions depend on the spatial distribution of radiation on the input surface and therefore on the direction of incidence of the plane wave.

3. The assembly of claim 1, wherein the wavelength converting member comprises a plurality of wavelength converting elements and a concentration of the wavelength converting elements per unit area when viewed in a direction perpendicular to the input surface varies as a function of position over the input surface.

4. The assembly of claim 3, wherein the variation in concentration per unit area is such that an average concentration of the wavelength converting elements per unit area, averaged over at least 5% of the input surface, varies by at least 1% as a function of position over the input surface.

5. The assembly of claim 3, wherein the wavelength converting elements are distributed in a medium.

6. The assembly of claim 5, wherein a thickness of the medium in a direction perpendicular to a nearest portion of the input surface varies as a function of position over the input surface.

7. The assembly of claim 5, wherein the thickness varies by at least 1% as a function of position over the input surface.

8. The assembly of claim 5, wherein:
the number of the wavelength converting elements per unit volume varies as a function of position, at least in a direction parallel to the input surface; and
the variation in number per unit volume is such that an average number per unit volume, averaged over at least 5% of the medium, varies by at least 1% as a function of position, at least in a direction parallel to the input surface.

9. (canceled)

10. The assembly of claim 1, wherein an absorbance within the concentration stage is such that a beam of radiation after conversion within the wavelength converting member would be reduced in amplitude by at least 1% if the radiation were to travel along the entirety of a shortest optical path between two different ones of the plurality of detectors.

11. The assembly of claim 1, wherein:
the concentration stage comprises a plurality of radiation guides;
each radiation guide has an elongate form with a length that is at least five times longer than all dimensions of the radiation guide perpendicular to the longitudinal axis;
each radiation guide comprises a portion of the wavelength converting member and is thereby configured to convert radiation to longer wavelength radiation within the radiation guide;
the input surface of the concentration stage comprises at least a portion of an outer lateral surface of each of the radiation guides; and
each of the radiation guides is configured to guide the converted radiation to a longitudinal end surface of the radiation guide, the output surface of the concentration stage comprising at least a portion of the longitudinal end surface of each of the radiation guides.

12. The assembly of claim 11, wherein each of one or more of the radiation guides has a circular cross-section perpendicular to the longitudinal axis.

13. The assembly of claim 11, wherein:
wavelength converting elements are distributed non-uniformly through a cross-section of each of one or more of the radiation guides, averaged over the length of the radiation guide; and
more than 95% of the wavelength converting elements are located within a range of azimuthal angles of less than 330 degrees relative to the longitudinal axis, averaged over the length of the radiation guide.

14. (canceled)

15. The assembly of claim 11, wherein an elongate region within each of one or more of the radiation guides comprises substantially no wavelength converting elements.

16. The assembly of claim 11, wherein each of one or more of the radiation guides comprises a first region encompassing all material within a first radius relative to the longitudinal axis and a second region encompassing all material from the first radius to a second radius relative to the longitudinal axis, wherein substantially all of the wavelength converting elements within the radiation guide are located in the second region.

17. The assembly of claim 16, wherein the first radius is at least 25% of the second radius.

18. The assembly of claim 16, wherein the radiation guide has a circular cross-section along its whole length and the second radius is equal to the radius of the circular cross-section.

19. The assembly of claim 16, wherein a refractive index of the first region is within 10% of the refractive index of the second region.

20. The assembly of claim 11, wherein each of one or more of the radiation guides comprises a core of an optical fibre.

21. The assembly of claim 20, wherein the radiation guide further comprises an outer layer on the core of the optical fibre, and wherein the conversion of the received radiation to longer wavelength radiation is performed at least partially in the outer layer.

22. The assembly of claim 1, wherein:
the concentration stage comprises a confinement structure that is configured substantially to allow passage of radiation having a wavelength suitable for conversion by the wavelength converting member from the outside of the confinement structure to the inside of the confinement structure, and substantially to block passage of radiation that has been converted by the wavelength converting member from the inside of the confinement structure to the outside of the confinement structure;
the wavelength converting member is located within the confinement structure; and
the confinement structure is configured to concentrate radiation onto the output surface of the concentration stage.

23. (canceled)

24. (canceled)

25. The assembly of claim 22, wherein the confinement structure comprises two substantially planar elements and the wavelength converting member is located in between the two substantially planar elements.

26. The assembly of claim 1 in which the conversion of the received radiation to longer wavelength radiation comprises one or more of the following: conversion of infrared or near-infrared radiation to infrared radiation or near-infrared radiation having a longer wavelength, conversion of UV radiation to visible radiation, conversion of UV radiation to infrared or near-infrared radiation, conversion of visible radiation to visible radiation having a longer wavelength, and conversion of visible radiation to infrared or near-infrared radiation.

27. The assembly of claim 1, further comprising:
a decoder for obtaining information modulated onto radiation received by the plurality of detectors.

28. The assembly of claim 27, wherein in the case where plural different units of information are respectively modulated onto plural different radiation beams, and each radiation beam is incident onto the optical element from a different direction, the decoder is configured to be able to distinguish between each of the plural different units of information.

29. The assembly of claim 1, wherein the optical element comprises a lens.

30. The assembly of claim 29, wherein the optical element comprises a Fresnel lens.

31. The assembly of claim 29, wherein the optical element comprises a diffractive lens.

32. The assembly of claim 1, wherein the concentration stage is configured such that in use an average photon flux density on the output surface is higher than an average photon flux density on the input surface.

33. The assembly of claim 1, wherein the plurality of detectors comprises at least two detectors which receive radiation output from portions of the output surface that are non-parallel.

34. A data communications system, comprising:
the receiver assembly of claim 1; and
a transmitter assembly comprising a plurality of transmitters, each of the transmitters being configured to transmit a beam of radiation onto the optical element of the receiver assembly from a different direction.

35. The system of claim 34, wherein the transmitter assembly is configured to transmit a different unit of information from each of the transmitters.

36. The system of claim 35, wherein the receiver assembly is configured to obtain the units of information from the beams of radiation received by the receiver assembly and to distinguish between the different units of information by virtue of the different directions of incidence of the beams of radiation onto the optical element of the receiver assembly.

37. A data communications method, comprising the following steps:
using a concentration stage to receive radiation via an input surface and output concentrated radiation via an output surface;
using a wavelength converting member in the concentration stage to convert radiation to longer wavelength radiation;
providing an optical element configured such that if a plane wave of radiation is incident on the optical element a spatial distribution of radiation derived from the plane wave on the input surface of the concentration stage varies as a function of a direction of incidence of the plane wave relative to the optical element; and
detecting radiation output from the output surface using a plurality of detectors, each detector being configured to detect radiation output from a different portion of the output surface.

38. The method of claim 37, comprising using the optical element to increase a variance in amplitude of radiation incident on the input surface relative to if the optical element were not present.

39. (canceled)

40. (canceled)

41. (canceled)

42. (canceled)
